(19) United States
(12) Patent Application Publication
(10) Pub. No.: US 2023/0112331 A1
(43) Pub. Date: Apr. 13, 2023

(54) CURVED DISPLAY DEVICE

(71) Applicant: Samsung Display Co., LTD., Yongin-si (KR)

(72) Inventors: Jiye LEE, Hwaseong-si (KR); Sooyeon KIM, Namyangju-si (KR); Hee-Jeong SEO, Hwaseong-si (KR); Jongsoo KIM, Seongnam-si (KR); Heen Dol KIM, Hwaseong-si (KR); Chae Hee PARK, Suwon-si (KR); Youngsuk JUNG, Hwaseong-si (KR)

(21) Appl. No.: 17/963,887

(22) Filed: Oct. 11, 2022

(30) Foreign Application Priority Data
Oct. 12, 2021 (KR) 10-2021-0135277

(51) Int. Cl. H01L 33/20; H05K 1/18; H01L 33/62; H01L 27/15

(52) U.S. Cl. CPC H01L 33/20; H05K 1/189; H01L 33/62; H01L 27/156; H05K 2201/10128

(57) ABSTRACT

A display device includes: a display panel comprising a display area including a plurality of pixels and a non-display area disposed around the display area; and a plurality of flexible printed circuit boards disposed in the non-display area along a first edge of the display panel, where distances of a first end portion of each of the flexible printed circuit boards from the first edge are different from each other.

This application claims priority to Korean Patent Application No. 10-2021-0135277, filed on Oct. 12,2021, and all the benefits accruing therefrom under 35 U.S.C. 119, the content of which in its entirety is herein incorporated by reference.

### BACKGROUND

### 1. Field

The disclosure relates to a curved display device.

### 2. Description of the Related Art

A flat panel display may include a liquid crystal display (“LCD”), a plasma display panel (“PDP”), an organic light emitting diode (“OLED”) device, a field effect display (“FED”), an electrophoretic display device, and the like.

In general, a display device includes a display panel including a plurality of pixels, and a driver for driving the pixels. The driver includes a gate driver connected to the pixels and a data driver connected to the pixels in one side of the display panel.

The data driver may include a plurality of driving chips, and the driving chips may be disposed on flexible circuit films. The flexible circuit films may be connected to the display panel and a printed circuit board. The flexible circuit films may be bent toward a rear surface of the display panel, and the printed circuit board may be disposed on the rear surface of the display panel, which is a back surface of the display panel.

### SUMMARY

Recently, a curved display device has been developed, and the curved display device may be manufactured by deforming a flat display panel into a curved shape. In such a curved display device, when the display panel is deformed into a curved shape, the flexible circuit films may be separated from or peeled off from the display panel due to a stress generated in the flexible circuit films connected to the display panel.

Embodiments provide a display device with improved durability by preventing peeling of flexible circuit films due to a stress during a manufacturing process of a curved display device.

An embodiment of a display device according to the invention includes a display panel including a display area including a plurality of pixels and a non-display area disposed around the display area; and a plurality of flexible printed circuit boards disposed in the non-display area along a first edge of the display panel, where distances of a first end portion of each of the flexible printed circuit boards from the first edge are different from each other.

In an embodiment, the first edge may be parallel to a first direction, and the display panel may be curved around an axis in a second direction which is perpendicular to the first direction.

In an embodiment, the display panel may include a second edge and a third edge, which are connected to the first edge and opposite to each other in the first direction, the flexible printed circuit boards may include a first flexible printed circuit board disposed at a center of the display panel and a second flexible printed circuit board disposed adjacent to the second edge of the display panel, and a first distance between the first end portion of the first flexible printed circuit board and the first edge may be greater than a second distance between the first end portion of the second flexible printed circuit board and the first edge.

In an embodiment, the flexible printed circuit boards may further include a third flexible printed circuit board and a fourth flexible printed circuit board, which are disposed between the first flexible printed circuit board and the second flexible printed circuit board, the third flexible printed circuit board may be disposed closer to the first flexible printed circuit board than the second flexible printed circuit board is, the fourth flexible printed circuit board may be disposed closer to the second flexible printed circuit board than the first flexible printed circuit board is, and a third distance between the first end portion of the third flexible printed circuit board and the first edge may be smaller than a fourth distance between the first end portion of the fourth flexible printed circuit board and the first edge.

In an embodiment, the first distance may be greater than the third distance, and the second distance may be smaller than the fourth distance.

In an embodiment, the display device may further include: a plurality of first pad portions disposed in the display panel; and a plurality of second pad portions disposed in each of the flexible printed circuit boards, where the first pad portions may be in contact with the second pad portions.

In an embodiment, the display panel may include a second edge and a third edge, which are connected to the first edge and opposite to each other in the first direction, and distances of each of the second pad portions from the first end portion may be different from each other.

In an embodiment, The second pad portions may be disposed to be farther away from the first end portions as they are disposed closer to the second edge or the third edge from a center of the display panel in the first direction.

An embodiment of a display device according to the invention includes: a display panel including a display area including a plurality of pixels and a non-display area disposed around the display area; a plurality of flexible printed circuit boards disposed in the non-display area along a first edge of the display panel; a plurality of first pad portions disposed in the display panel; and a plurality of second pad portions disposed in each of the flexible printed circuit boards, where distances of a first end portion of each of the flexible printed circuit boards from the first edge are different from each other, and distances of each of the second pad portions from the first end portion are different from each other.

An embodiment of a display device according to the invention includes: a display panel including a display area including a plurality of pixels and a non-display area disposed around the display area, where the display panel includes a first edge which is parallel to a first direction, and a second edge and a third edge which are connected to the first edge and opposite to each other in the first direction; a plurality of flexible printed circuit boards disposed in the non-display area along a first edge of the display panel; a plurality of first pad portions disposed in the display panel; and a plurality of second pad portions disposed in each of the flexible printed circuit boards and connected to the first pad portions, where the second pad portions may be disposed to be farther away from a first end portion of each of the flexible printed circuit boards as being closer to the second edge or the third edge from a center of the display panel in the first direction.

According to the embodiments of the invention, a display device may have improved durability by preventing peeling of flexible circuit films due to a stress during a manufacturing process of a curved display device.

### BRIEF DESCRIPTION OF THE DRAWINGS

FIG. 1 illustrates a schematic top plan view of a display device according to an embodiment.

FIG. 2 illustrates a cross-sectional view showing an embodiment of an interlayer structure of one pixel of a display device according to an embodiment.

FIG. 3 illustrates a cross-sectional view showing an embodiment of an interlayer structure of one pixel of a display device according to an embodiment.

FIG. 4 illustrates a cross-sectional view showing an embodiment of an interlayer structure of one pixel of a display device according to an embodiment.

FIG. 5 illustrates a cross-sectional view of a display device according to an embodiment.

FIG. 6 illustrates a perspective view of a display device according to an embodiment.

FIG. 7 illustrates a schematic perspective view showing a rear surface of a portion of a display device according to an embodiment.

FIG. 8 illustrates a layout view showing a portion of a display device according to an embodiment.

FIG. 9 and FIG. 10 each illustrate a top plan view showing a portion of a display device according to an alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The accompanying drawings are provided only in order to allow embodiments disclosed in the present specification to be easily understood and are not to be interpreted as limiting the spirit disclosed in the present specification, and it is to be understood that the embodiments includes all modifications, equivalents, and substitutions without departing from the scope and spirit of the embodiments.

Further, since sizes and thicknesses of constituent members shown in the accompanying drawings are arbitrarily given for better understanding and ease of description, the embodiments is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Further, in the specification, the phrase “in a plan view” means when an object portion is viewed from above, and the phrase “in a cross-sectional view” means when a cross-section taken by vertically cutting an object portion is viewed from the side.

In addition, in the specification, “connected” means that two or more components are not only directly connected, but two or more components are connected indirectly through other components, physically connected as well as being electrically connected, or it may have been referred to as different names depending on the location or function, but may mean integral.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

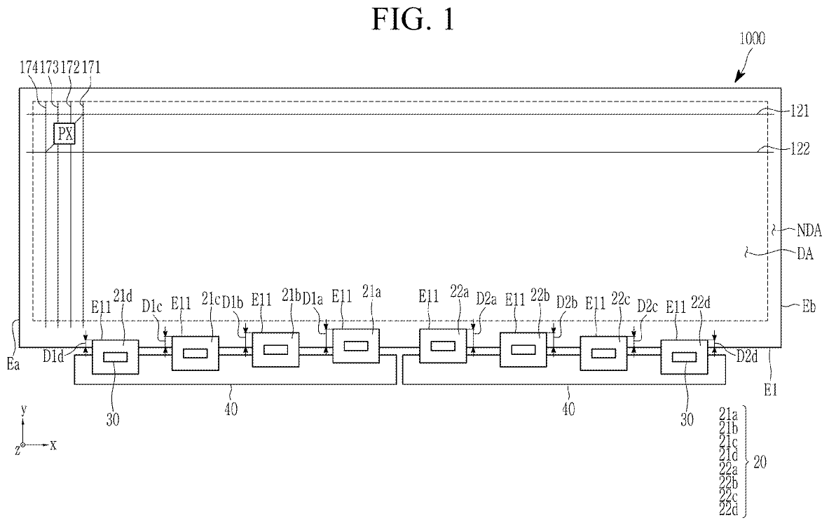

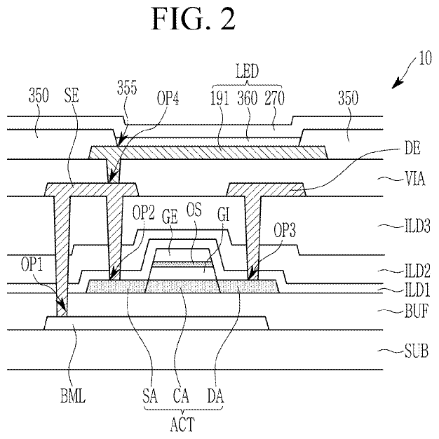

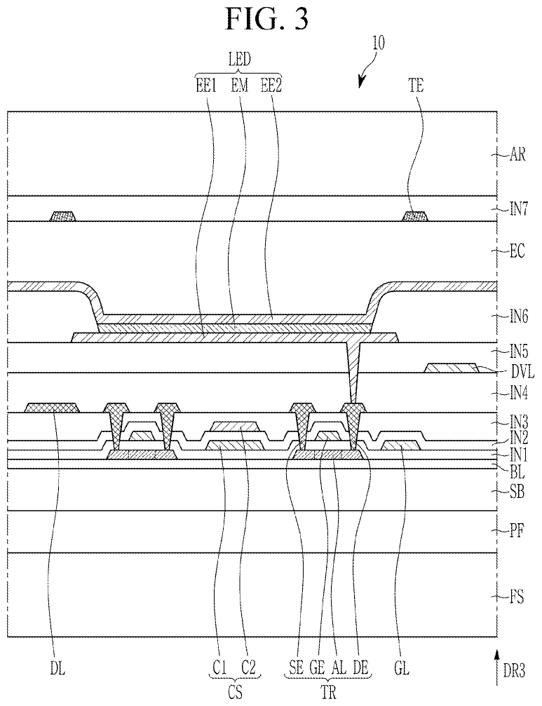

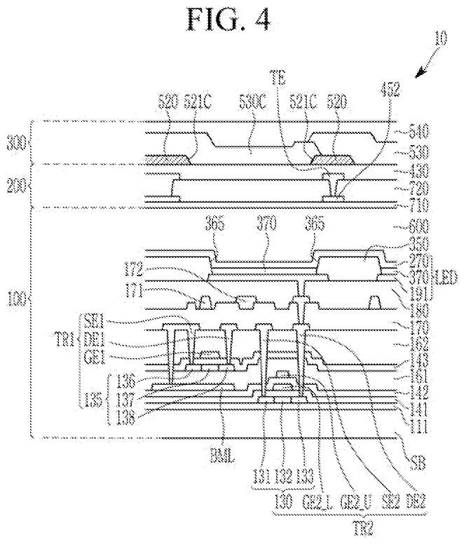

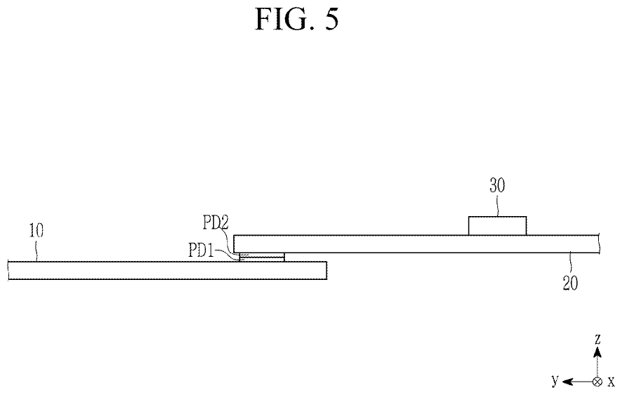

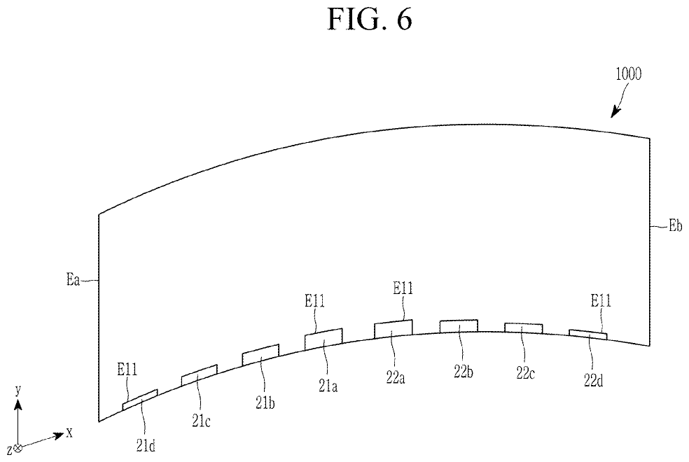

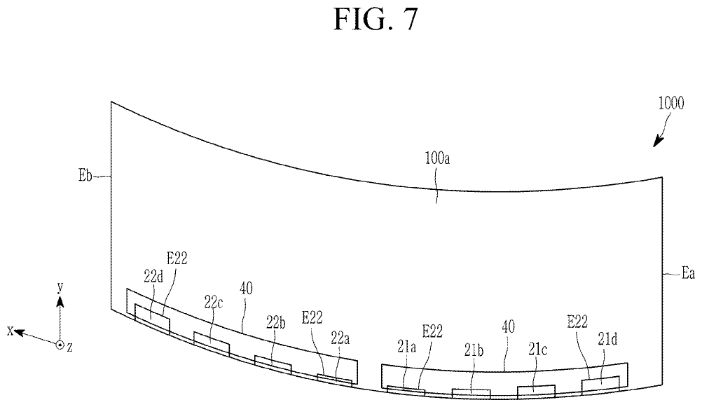

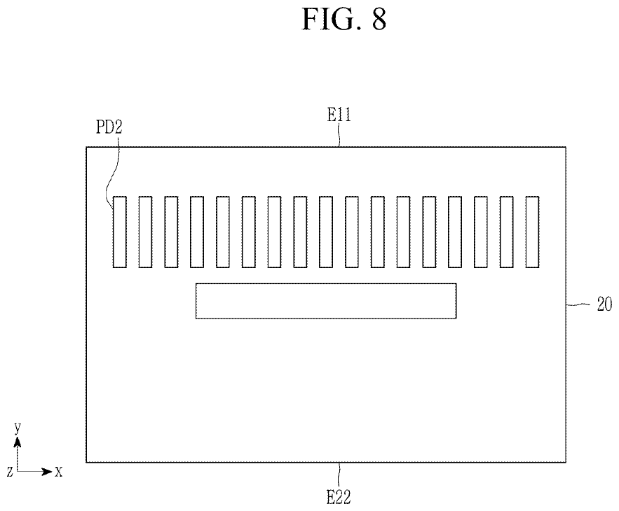

Hereinafter, a display device 1000 according to an embodiment will be described with reference to FIG. 1 to FIG. 6. FIG. 1 illustrates a schematic top plan view of a display device according to an embodiment, FIG. 2 illustrates a cross-sectional view showing an embodiment of an interlayer structure of one pixel of a display device according to an embodiment, FIG. 3 illustrates a cross-sectional view showing an embodiment of an interlayer structure of one pixel of a display device according to an embodiment, FIG. 4 illustrates a cross-sectional view showing an embodiment of an interlayer structure of one pixel of a display device according to an embodiment, FIG. 5 illustrates a cross-sectional view of a display device according to an embodiment, FIG. 6 illustrates a perspective view of a display device according to an embodiment, FIG. 7 illustrates a schematic perspective view showing a rear surface of a portion of a display device according to an embodiment, and FIG. 8 illustrates a layout view showing a portion of a display device according to an embodiment.

Referring to FIGS. 1 to 8, the display device 1000 according to an embodiment may include a display panel 10, a flexible printed circuit board 20, an integrated circuit chip 30, and a printed circuit board 40.

The display panel 10 includes a display area DA corresponding to a screen on which an image is displayed and a non-display area NDA, and circuits and/or signal lines for generating and/or transferring various signals and voltages applied to the display area DA are disposed in the non-display area NDA. The non-display area NDA may surround a periphery of the display area DA. In FIG. 1, a boundary between the display area DA and the non-display area NDA is indicated by a dotted-line rectangle.

Pixels PX are disposed in a matrix form in the display area DA of the display panel 10. In addition, signal lines such as a first scan line 121, a second scan line 122, a data line 171, a driving voltage line 172, a common voltage line 173, and an initializing voltage line 174 may be disposed in the display area DA.

The first scan line 121 and the second scan line 122 may extend substantially in a first direction x. The data line 171, the driving voltage line 172, the common voltage line 173, and the initialization voltage line 174 may extend substantially in a second direction y crossing the first direction x. Here, a third direction z, which is perpendicular to the first direction x and the second direction y, may be a thickness direction of the display panel 10.

In another embodiment, at least one of the driving voltage line 172, the common voltage line 173, and the initialization voltage line 174 may include a voltage line extending substantially in the first direction x and a voltage line extending substantially in the second direction y, and may be arranged in the form of a mesh.

Each of the pixels PX may be connected to signal lines including a first scan line 121, a second scan line 122, a data line 171, a driving voltage line 172, a common voltage line 173, an initialization voltage line 174, etc., to receive a first scan signal, a second scan signal, a data voltage, a driving voltage, a common voltage, an initialization voltage, and the like from the signal lines.

The pixel PX may include a light emitting element such as a light emitting diode.

Touch electrodes for detecting a user's contact touch and/or a non-contact touch may be disposed in the display area DA of the display panel 10.

A stacked structure of a portion of the pixel PX in the display area DA of the display panel 10 of an embodiment of the display device 1000 will hereinafter be described in detail with reference to FIG. 2 to FIG. 4.

Referring first to FIG. 2, in an embodiment, the display panel 10 includes a substrate SUB. The substrate SUB may be a rigid substrate or a flexible substrate capable of bending, folding, rolling, or the like. The substrate SUB may include at least one selected from polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the embodiment is not limited thereto, and the substrate SUB may include other materials.

A light blocking layer BML is disposed on the substrate SUB. The light blocking layer BML may include at least one selected from aluminum (Al), silver (Ag), magnesium (Mg), gold (Au), nickel (Ni), chromium (Cr), calcium (Ca), molybdenum (Mo), titanium (Ti), tungsten (W), copper (Cu) and a metal oxide, and may have a single or multi-layered structure, each layer therein including at least one selected from the materials listed above. However, the embodiment is not limited thereto, and the light blocking layer BML may include other materials.

A buffer layer BUF is disposed on the light blocking layer BML. The buffer layer BUF may include a silicon oxide (SiOₓ), a silicon nitride (SiNₓ), a silicon oxynitride (SiOₓN_{y}), or amorphous silicon (Si). However, the embodiment is not limited thereto, and the buffer layer BUF may include other materials.

In an embodiment, a first opening OP1 may be defined through the buffer layer BUF to overlap the light blocking layer BML. In such an embodiment, a first electrode SE may be connected to the light blocking layer BML through the first opening OP1.

A semiconductor layer ACT is disposed on the buffer layer BUF. The semiconductor layer ACT may include an oxide semiconductor. The oxide semiconductor may include at least one selected from indium (In), tin (Sn), zinc (Zn), hafnium (Hf), and aluminum (Al). In an embodiment, for example, the semiconductor layer ACT may include an indium-gallium-zinc oxide (“IGZO”). However, the embodiment is not limited thereto, and the semiconductor layerACT may include other materials.

The semiconductor layer ACT may include a channel area CA overlapping the gate electrode GE, and a first area SA and a second area DA′ disposed at opposite sides of the channel area CA.

A gate insulating layer GI may be disposed on the semiconductor layer ACT. The gate insulating layer GI may include a silicon oxide (SiOₓ), a silicon nitride (SiNₓ), or a silicon oxynitride (SiOₓN_{y}), and may have a single or multi-layer structure, each layer therein including at least one selected from the materials listed above. However, the embodiment is not limited thereto, and the gate insulating layer GI may include other materials.

The gate insulating layer GI may be disposed to overlap the channel area CA of the semiconductor layerACT.

An oxygen supply layer OS is disposed on the gate insulating layer GI. The oxygen supply layer OS may supply oxygen to the semiconductor layer ACT, and may increase reliability of the semiconductor layer ACT including an oxide semiconductor.

The semiconductor layer ACT including the oxide semiconductor may exhibit a conductor-like property due to an oxygen vacancy therein, making it difficult to use as a transistor, or may not be suitable for use as a transistor due to a low threshold voltage thereof. In an embodiment, the semiconductor layer ACT may include the oxygen supply layer OS, so that the oxygen supply layer OS supplies oxygen to the semiconductor layer ACT (e.g., the oxygen supply layer OS for supplying oxygen to the semiconductor layer ACT may be included in the transistor), thereby ensuring reliability of the semiconductor layer ACT including the oxide semiconductor. In such an embodiment, excess oxygen contained in the oxygen supply layer OS is transferred to the semiconductor layer ACT by heat treatment or the like, and combines with the oxygen deficiency (e.g., the oxygen vacancy) in the semiconductor layer ACT to remove the oxygen deficiency. Accordingly, excessive oxygen deficiency in the semiconductor layer ACT may be removed, and reliability of the transistor including the semiconductor layer ACT may be secured.

A thickness of the oxygen supply layer OS may be about 30% to about 50% of that of the semiconductor layer ACT, but the embodiment is not limited thereto. The oxygen supply layer OS may be a metal oxide including indium, zinc, gallium, or tin. In an embodiment, for example, the oxygen supply layer OS may include at least one of IGZO, indium tin oxide (“ITO”), indium tin gallium oxide (“ITGO”), indium zinc oxide (“IZO”), ZnO, and indium tin gallium zinc oxide (“ITGZO”). However, the embodiment is not limited thereto, and the oxygen supply layer OS may include other materials.

The semiconductor layer ACT and the oxygen supply layer OS may include a same material as each other. However, the embodiment is not limited thereto, and the semiconductor layer ACT and the oxygen supply layer OS may include different materials from each other. Alternatively, the oxygen supply layer OS may be omitted.

A gate conductive layer including a gate electrode GE may be disposed on the gate insulating layer GI and the oxygen supply layer OS. The gate conductive layer may include at least one selected from molybdenum (Mo), aluminum (Al), copper (Cu), titanium (Ti), and a metal oxide, and may have a single or multi-layer structure, each layer therein including at least one selected from the materials listed above. However, the embodiment is not limited thereto, and the gate electrode GE may include other materials.

The gate electrode GE may be formed in a same process as the gate insulating layer GI and the oxygen supply layer OS to have a same planar shape. The gate electrode GE may be disposed to overlap the semiconductor layer ACT in a direction that is perpendicular to a surface of the substrate SUB, or the third direction z.

A first interlayer insulating layer ILD1 may be disposed on the semiconductor layer ACT and the gate electrode GE, a second interlayer insulating layer ILD2 may be disposed on the first interlayer insulating layer ILD1, and a third interlayer insulating layer ILD3 may be disposed on the second interlayer insulating layer ILD2.

The first interlayer insulating layer ILD1 may include a low-hydrogen silicon nitride (SiNₓ), the second interlayer insulating layer ILD2 may include a silicon oxide (SiOₓ), and the third interlayer insulating layer ILD3 may include a silicon nitride (SiNₓ). However, the embodiment is not limited thereto, and the first interlayer insulating layer ILD1, the second interlayer insulating layer ILD2, and the third interlayer insulating layer ILD3 may include other materials. The first interlayer insulating layer ILD1, the second interlayer insulating layer ILD2 and the third interlayer insulating layer ILD3 may be integrated into one insulating layer or two insulating layers.

In an embodiment, a first opening OP1 overlapping the light blocking layer BML, a second opening OP2 overlapping the first area SA of the semiconductor layer ACT, and a third opening OP3 overlapping the second area DA may be defined through the first interlayer insulating layer ILD1, the second interlayer insulating layer ILD2, and the third interlayer insulating layer ILD3. The first opening OP1 overlapping the light blocking layer BML may be defined through the first interlayer insulating layer ILD1, the second interlayer insulating layer ILD2, the third interlayer insulating layer ILD3 and the buffer layer BUF.

A data conductive layer including the first electrode SE and the second electrode DE is disposed on the third interlayer insulating layer ILD3. The data conductive layer may include at least one selected from aluminum (Al), silver (Ag), magnesium (Mg), gold (Au), nickel (Ni), chromium (Cr), calcium (Ca), molybdenum (Mo), titanium (Ti), tungsten (W), copper (Cu) and a metal oxide, and may have a single or multi-layered structure, each layer therein including at least one selected from the materials listed above. However, the embodiment is not limited thereto, and the data conductive layer may include other materials.

The first electrode SE may contact the light blocking layer BML through the first opening OP1, and may contact the first area SA of the semiconductor layer ACT through the second opening OP2. The second electrode DE may contact the second area DA of the semiconductor layer ACT through the third opening OP3.

An insulating layer VIA is disposed on the data conductive layer. The insulating layer VIA may include an organic insulating material such as a general purpose polymer, e.g., poly(methyl methacrylate) (“PMMA”) or polystyrene (“PS”), a polymer derivative having a phenolic group, an acrylic polymer, an imide polymer, a polyimide, a siloxane polymer, etc., and the insulating layer VIA may include a silicon nitride (SiNₓ). However, the embodiment is not limited thereto, and the insulating layer VIA may include other materials. In an embodiment, the insulating layer VIA may be formed to include or defined by two insulating layers including different materials from each other.

In an embodiment, a fourth opening OP4 may be defined through the insulating layer VIA to overlap the first electrode SE. A first electrode 191 may be disposed on the insulating layer VIA. A partition wall (or pixel defining layer) 350 is disposed on the insulating layer VIA and the first electrode 191. In an embodiment, an opening 355 may be defined through the partition wall 350 to overlap the first electrode 191. An emission layer 360 may be disposed in the opening 355. A second electrode 270 may be disposed on the partition wall 350 and the emission layer 360. The first electrode 191, the emission layer 360, and the second electrode 270 may constitute a light emitting diode LED.

Next, the interlayer structure of an alternative embodiment of the display panel 10 will be described with reference to FIG. 3. Referring to FIG. 3, the display panel 10 may include a substrate SB, a transistor TR disposed on the substrate SB, and a light emitting diode LED connected to the transistor TR. The light emitting diode LED may correspond to the pixel.

The substrate SB may be a flexible substrate including or made of a polymer such as a polyimide, a polyamide, or a polyethylene terephthalate. However, the embodiment is not limited thereto, and the substrate SB may include other materials.

The substrate SB may include a barrier layer for preventing penetration of moisture, oxygen, etc. In an embodiment, for example, the substrate SB may include one or more polymer layers and one or more barrier layers, and the polymer layers and the barrier layers may be alternately stacked.

A buffer layer BL may be disposed on the substrate SB. The buffer layer BL may include an inorganic insulating material such as a silicon oxide and a silicon nitride. However, the embodiment is not limited thereto, and the buffer layer BL may include other materials.

A semiconductor layer AL of the transistor TR may be disposed on the buffer layer BL, and an insulating layer IN1 may be disposed on the semiconductor layer AL. The semiconductor layer AL may include a source region and a drain region, and a channel region between these regions. The semiconductor layer AL may include a semiconductor material such as polysilicon, an oxide semiconductor, and amorphous silicon.

A first conductor, which may include a gate electrode GE of the transistor TR, a gate line GL, and a first electrode C1 of a capacitor CS, may be disposed on the insulating layer IN1.

An insulating layer IN2 may be disposed on the first conductor. A second conductor that may include a second electrode C2 of the capacitor CS and the like may be disposed on the insulating layer IN2. The first conductor and/or the second conductor may include a metal such as molybdenum (Mo), copper (Cu), aluminum (Al), silver (Ag), chromium (Cr), tantalum (Ta), titanium (Ti), or an alloy thereof. However, the embodiment is not limited thereto, and the first conductor and/or the second conductor may include other materials.

An insulating layer IN3 may be disposed on the insulating layer IN2 and the second conductor. The insulating layers IN1, IN2, and IN3 may include an inorganic insulating material.

A third conductor that may include a source electrode SE and a drain electrode DE, a data line DL, and the like of the transistor TR may be disposed on the insulating layer IN3. The source electrode SE and the drain electrode DE may be connected to a source region and a drain region of the semiconductor layer AL through openings of the insulating layers IN1, IN2, and IN3, respectively.

An insulating layer IN4 may be disposed on the third conductor. A fourth conductor that may include a driving voltage line DVL or the like may be disposed on the insulating layer IN4. The third conductor and the fourth conductor include or are made of a metal such as aluminum (Al), copper (Cu), silver (Ag), molybdenum (Mo), chromium (Cr), gold (Au), platinum (Pt), palladium (Pd), tantalum (Ta), tungsten (W), titanium (Ti), or nickel (Ni), or a metal alloy. However, the embodiment is not limited thereto, and the third conductor may include other materials.

An insulating layer IN5 may be disposed on the fourth conductor. The insulating layers IN4 and IN5 may include an organic insulating material.

A first electrode EE1 of the light emitting diode LED is disposed on the insulating layer IN5. The first electrode EE1 may be referred to as a pixel electrode. The first electrode EE1 may be connected to the drain electrode DE through openings of the insulating layers IN4 and IN5 to receive a data signal for controlling luminance of a light emitting diode LED. The transistor TR to which the first electrode EE1 is connected may be a driving transistor ora transistor that is electrically connected to the driving transistor.

An insulating layer IN6 may be disposed on the insulating layer IN5. The insulating layer IN6 may be referred to as a pixel defining layer, and an opening may be defined through the insulating layer IN6 to overlap the first electrode EE1. The emission member EM including an emission layer may be disposed above the first electrode EE1 in the opening of the insulating layer IN6, and a second electrode EE2 may be disposed on the emission member EM. The second electrode EE2 may be referred to as a common electrode.

The first electrode EE1, the emission member EM, and the second electrode EE2 may constitute a light emitting diode LED, which may be an organic light emitting diode. The first electrode EE1 and the second electrode EE2 may serve as an anode and a cathode of the light emitting diode LED, respectively.

An encapsulation layer EC may be disposed on the second electrode EE2. The encapsulation layer EC may encapsulate a light emitting diode LED to prevent moisture or oxygen from penetrating from the outside. The encapsulation layer EC may be a thin film encapsulation layer including one or more inorganic material layers and one or more organic material layers.

A touch sensor layer including a touch electrode TE may be disposed on the encapsulation layer EC. The touch electrode TE may have a mesh shape having an opening overlapping the light emitting diode LED. A buffer layer may be disposed between the encapsulation layer EC and the touch sensor layer. An insulating layer IN7 covering the touch electrode TE may be disposed on the touch sensor layer.

An anti-reflection layer AR for reducing external light reflection may be disposed on the insulating layer IN7. The anti-reflection layer AR may include a polarization layer. The anti-reflection layer AR may be attached by an adhesive, or may be disposed on the insulating layer IN7. An anti-reflection effect may be obtained by forming the encapsulation layer EC, the touch sensor layer, and/or the insulating layer IN7 to have a refractive index matching structure, instead of the anti-reflection layer AR. Layers disposed between the substrate SB and the anti-reflective layer AR may correspond to a pixel layer PL.

A protection film PF may be disposed to protect the display panel 10 below the substrate SB. The protection film PF may include or be made of a polymer such as polyethylene terephthalate, polyethylene naphthalate, or polyimide.

A functional sheet FS including at least one selected from a cushion layer, a heat dissipation sheet, a light blocking sheet, a waterproof tape, and an electromagnetic barrier layer may be disposed under the protection film PF. The functional sheet FS may not be disposed on a pad portion.

The positions and disposals of the above devices may be variously changed depending on designs.

Next, the interlayer structure of another alternative embodiment of the display panel 10 will be described with reference to FIG. 4. The display panel 10 may include a display unit 100, a touch unit 200, and an anti-reflection unit 300. The touch unit 200 may be disposed between the display unit 100 and the anti-reflection unit 300.

A buffer layer 111 is disposed on the substrate SB. The buffer layer 111 is disposed between the substrate SB and the semiconductor layer (e.g., the semiconductor layer including the second semiconductor 130) to block impurities from the substrate SB during a crystallization process for forming polycrystalline silicon, thereby improving a characteristic of the polycrystalline silicon.

The buffer layer 111 may include an inorganic insulating material such as a silicon oxide (SiOₓ), a silicon nitride (SiNₓ), and a silicon oxynitride (SiOₓN_{y}). The buffer layer 111 may include amorphous silicon (Si). However, the embodiment is not limited thereto, and the buffer layer 111 may include other materials.

A second semiconductor 130 may be disposed on the buffer layer 111. The second semiconductor 130 may include a polycrystalline silicon material. That is, the second semiconductor 130 may be formed as a polycrystalline semiconductor. The second semiconductor 130 may include a source region 131, a channel region 132, and a drain region 133.

The source region 131 of the second semiconductor 130 may be connected to a second source electrode SE2, and the drain region 133 of the second semiconductor 130 may be connected to a second drain electrode DE2.

A first gate insulating layer 141 may be disposed on the second semiconductor 130

The first gate insulating layer 141 may have a single or multi-layered structure including at least one selected from a silicon nitride, a silicon oxide, a silicon oxynitride, and the like. However, the embodiment is not limited thereto, and the first gate insulating layer 141 may include other materials.

A second gate lower electrode GE2_L may be disposed on the first gate insulating layer 141. The second gate lower electrode GE2_L may include at least one selected from molybdenum (Mo), aluminum (Al), copper (Cu), and titanium (Ti), and may have a single or multi-layered structure, each layer therein including at least one selected from the materials listed above. However, the embodiment is not limited thereto, and the second gate lower electrode GE2_L may include other materials.

A second gate insulating layer 142 may be disposed on the second gate lower electrode GE2_L. The second gate insulating layer 142 may include at least one selected from a silicon nitride, a silicon oxide, a silicon oxynitride, and the like. The second gate insulating layer 142 may have a single or multi-layered structure including at least one selected from a silicon nitride, a silicon oxide, a silicon oxynitride, and the like. However, the embodiment is not limited thereto, and the second gate insulating layer 142 may include other materials.

A second gate upper electrode GE2_U may be disposed on the second gate insulating layer 142. The second gate lower electrode GE2_L and the second gate upper electrode GE2_U may overlap each other with the second gate insulating layer 142 therebetween. The second gate upper electrode GE2_U and the second gate lower electrode GE2_L constitute a second gate electrode. The second gate electrode may overlap the channel region 132 of the second semiconductor 130 in a direction that is perpendicular to the substrate SB.

Each of the second gate upper electrode GE2_U and the gate line (the gate line may be in a same layer as the second gate upper electrode GE2_U) may include at least one selected from molybdenum (Mo), aluminum (Al), copper (Cu), silver (Ag), chromium (Cr), tantalum (Ta), titanium (Ti), etc., and may have a single or multi-layered structure, each layer therein including at least one selected from the materials listed above. However, the embodiment is not limited thereto, and the second gate upper electrode GE2_U and the gate line may include other materials.

A metal layer BML (which may be referred to as the light blocking layer BML, similar to this hereinafter) defined by a same layer as that of the second gate upper electrode GE2_U and the gate line may be disposed on the second gate insulating layer 142, and may overlap the first transistor TR1 to be described later. The metal layer BML may be connected to the source electrode of the first transistor TR1, and may serve as a lower gate electrode.

The second semiconductor 130, the second gate upper electrode GE2_U, the second gate lower electrode GE2_L, the second source electrode SE2, and the second drain electrode DE2 constitute the second transistor TR2. The second transistor TR2 may be a driving transistor connected to the light emitting diode LED, and may be formed as or defined by a transistor including a polycrystalline semiconductor.

A first interlayer insulating layer 161 may be disposed on the second upper gate electrode GE2_U. The first interlayer insulating layer 161 may include a silicon nitride, a silicon oxide, a silicon oxynitride, and the like. In an embodiment, the first interlayer insulating layer 161 may be formed as a multilayer in which a layer including a silicon nitride and a layer including a silicon oxide are stacked one on another. In such an embodiment, in the first interlayer insulating layer 161, the layer including the silicon nitride may be disposed closer to the substrate SB than the layer including the silicon oxide. However, the embodiment is not limited thereto, and the first interlayer insulating layer 161 may include other materials.

A first semiconductor 135 may be disposed on the first interlayer insulating layer 161. The first semiconductor 135 may overlap the metal layer BML.

The first semiconductor 135 may include an oxide semiconductor. The oxide semiconductor may include at least one selected from indium (In) oxide, tin (Sn) oxide, zinc (Zn) oxide, hafnium (Hf) oxide, and aluminum (Al) oxide. In an embodiment, for example, the first semiconductor 135 may include an IGZO. However, the embodiment is not limited thereto, and the first semiconductor 135 may include other materials.

The first semiconductor 135 includes a channel region 137, and a source region 136 and a drain region 138 disposed at opposite sides of the channel region 137. The source region 136 of the first semiconductor 135 may be connected to a first source electrode SE1, and the drain region 138 of the first semiconductor 135 may be connected to a first drain electrode DE1.

A third gate insulating layer 143 may be disposed on the first semiconductor 135. The third gate insulating layer 143 may include at least one selected from a silicon nitride, a silicon oxide, a silicon oxynitride, and the like. However, the embodiment is not limited thereto, and the third gate insulating layer 143 may include other materials.

The third gate insulating layer 143 may be disposed between the first gate electrode GE1 and the first semiconductor 135. That is, the third gate insulating layer 143 may overlap the channel region 137 of the first semiconductor 135, and may not overlap the source region 136 and/or the drain region 138. Accordingly, a length of the channel of the semiconductor may be shortened in a process of implementing high resolution.

A first gate electrode GE1 may be disposed on the third gate insulating layer 143.

The first gate electrode GE1 may overlap the channel region 137 of the first semiconductor 135 in a direction that is perpendicular to the substrate SB or a thickness direction of the substrate SB. The first gate electrode GE1 may include at least one selected from molybdenum (Mo), aluminum (Al), copper (Cu), and titanium (Ti), and may have a single or multi-layered structure, each layer therein including at least one selected from the materials listed above. In an embodiment, for example, the first gate electrode GE1 may include a lower layer containing titanium and an upper layer containing molybdenum, and the lower layer containing titanium may prevent diffusion of fluorine (F), which is an etching gas, during dry etching of the upper layer. However, the embodiment is not limited thereto, and the first gate electrode GE1 may include other materials.

The first semiconductor 135, the first gate electrode GE1, the first source electrode SE1, and the first drain electrode DE1 constitute the first transistor TR1. The first transistor TR1 may be a switching transistor for switching the second transistor TR2, and may be formed as or defined by a transistor including an oxide semiconductor.

A second interlayer insulating layer 162 may be disposed on the first gate electrode GE1. The second interlayer insulating layer 162 may include at least one selected from a silicon nitride, a silicon oxide, a silicon oxynitride, and the like. The second interlayer insulating layer 162 may be formed as a multilayer in which a layer including a silicon nitride and a layer including a silicon oxide are stacked one on another. However, the embodiment is not limited thereto, and the second interlayer insulating layer 162 may include other materials.

A first source electrode SE1 and a first drain electrode DE1, and a second source electrode SE2 and a second drain electrode DE2, may be disposed on the second interlayer insulating layer 162. The first source electrode SE1, the first drain electrode DE1, the second source electrode SE2, and the second drain electrode DE2 may include at least one selected from aluminum (Al), molybdenum (Mo), titanium (Ti), tungsten (W), and copper (Cu), for example, and may have a single or multi-layered structure, each layer therein including at least one selected from the materials listed above. In an embodiment, for example, the first source electrode SE1, the first drain electrode DE1, the second source electrode SE2, and the second drain electrode DE2 may have a triple layer structure including a lower layer including a refractory metal such as titanium, molybdenum, chromium, and tantalum, or an alloy thereof, an interlayer layer including at least one selected from an aluminum-based metal, a silver-based metal, and a copper-based metal with low resistivity, and an upper layer including a refractory metal such as titanium, molybdenum, chromium, or tantalum. However, the embodiment is not limited thereto, and the first source electrode SE1, the first drain electrode DE1, the second source electrode SE2, and the second drain electrode DE2 may include other materials.

The first source electrode SE1 may be connected to the source region 136 of the first semiconductor 135, and the first drain electrode DE1 may be connected to the drain region 138 of the first semiconductor 135. In addition, the first source electrode SE1 may be connected to the metal layer BML.

The second source electrode SE2 may be connected to the source region 131 of the second semiconductor 130, and the second drain electrode DE2 may be connected to the drain region 133 of the second semiconductor 130.

A first insulating layer 170 may be disposed on the first source electrode SE1, the first drain electrode DE1, the second source electrode SE2, and the second drain electrode DE2. The first insulating layer 170 may be an organic layer or an inorganic layer. In an embodiment, for example, the first insulating layer 170 may include a general purpose polymer such as PMMA or PS, a polymer derivative having a phenolic group, an organic insulating material such as an acrylic polymer, an imide polymer, a polyimide, an acrylic polymer, a siloxane polymer, etc. However, the embodiment is not limited thereto, and the first source electrode SE1 and the first insulating layer 170 may include other materials.

A connection electrode CE, a data line 171, and a driving voltage line 172 may be disposed on the first insulating layer 170. The connection electrode CE and the data line 171 may include at least one selected from aluminum (Al), silver (Ag), magnesium (Mg), gold (Au), nickel (Ni), chromium (Cr), calcium (Ca), molybdenum (Mo), titanium (Ti), tungsten (W), and copper (Cu), for example, and may have a single or multi-layered structure, each layer therein including at least one selected from the materials listed above. However, the embodiment is not limited thereto, and the connection electrodes CE and the date line 171 may include other materials.

The connection electrode CE is connected to the second drain electrode DE2.

A second insulating layer 180 may be disposed on the first insulating layer 170, the connection electrode CE, and the data line 171. The second insulating layer 180 may serve to eliminate and planarize a step structure thereunder to increase emission efficiency of a light emitting layer to be formed thereon. The second insulating layer 180 may include a general purpose polymer such as PMMA or PS, a polymer derivative having a phenolic group, an organic insulating material such as an acrylic polymer, an imide polymer, a polyimide, an acrylic polymer, a siloxane polymer, etc. However, the embodiment is not limited thereto, and the second insulating layer 180 may include other materials.

A pixel electrode 191 may be disposed on the second insulating layer 180. The pixel electrode 191 may be connected to the second drain electrode DE2 through a contact hole 185 of the second insulating layer 180.

The pixel electrode 191 may be individually disposed for each pixel PX. The pixel electrode 191 may include a metal such as silver (Ag), lithium (Li), calcium (Ca), aluminum (Al), magnesium (Mg), and gold (Au), and may also include a transparent conductive oxide (“TCO”) such as IZO and ITO. The pixel electrode 191 may be formed as a single layer including a metal material or a transparent conductive oxide, or a multiple layer, each layer therein including at least one selected from the materials listed above. In an embodiment, for example, the pixel electrode 191 may have a triple layer structure of ITO/Ag/ITO. However, the embodiment is not limited thereto, and the pixel electrode 191 may include other materials.

A pixel defining layer 350 may be disposed on the pixel electrode 191. The pixel defining 350 may include a general purpose polymer such as PMMA or PS, a polymer derivative having a phenolic group, an organic insulating material such as an acrylic polymer, an imide polymer, a polyimide, an acrylic polymer, a siloxane polymer, etc. The pixel defining layer 350 may include a black dye, and may not transmit light. However, the embodiment is not limited thereto, and the pixel defining layer 350 may include other materials.

In an embodiment, a pixel opening 365 may be defined through the pixel defining layer 350 to overlap the pixel electrode 191, and an emission layer 370 may be disposed within the pixel opening 365.

The emission layer 370 may include a material layer that emits light of a primary color such as red, green, or blue. The emission layer 370 may have a structure in which a plurality of material layers that emit light of different colors are stacked one on another.

In an embodiment, for example, the emission layer 370 may be an organic emission layer, and the organic emission layer may include a plurality of layers including at least one of an emission layer, a hole-injection layer, a hole-transporting layer, an electron-transporting layer, and an electron-injection layer. In an embodiment where the organic emission layer includes all of the above-listed layers, the hole-injection layer may be disposed on the pixel electrode 191 which is an anode, and the hole-transporting layer, the emission layer, the electron-transporting layer, and the electron-injection layer may be sequentially stacked thereon.

A common electrode 270 may be disposed on the emission layer 370 and the pixel defining layer 350. The common electrode 270 may be disposed in common in all the pixels PX, and may receive a common voltage through a common voltage transfer unit of the non-display area DA.

The common electrode 270 may include a reflective metal including at least one selected from calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), etc., or a TCO such as ITO or IZO. However, the embodiment is not limited thereto, and the common electrode 270 may include other materials.

The pixel electrode 191, the emission layer 370, and the common electrode 270 may constitute the light emitting diode LED. In an embodiment, the pixel electrode 191 may be an anode which is a hole-injection electrode, and the common electrode 270 may be a cathode which is an electron-injection electrode. However, the embodiment is not limited thereto, and the pixel electrode 191 may be a cathode and the common electrode 270 may be an anode depending on a driving method of an organic light emitting diode display.

When holes and electrons are injected from the pixel electrode 191 and the common electrode 270 into the emission layer 370, excitons formed by combining the injected holes and electrons are emitted when the holes and electrons fall from an excited state to a ground state.

The first transistor TR1, which is a part of a switching transistor of the display device according to an embodiment, may include an oxide semiconductor, and the second transistor TR2, which is a driving transistor, may include a polycrystalline semiconductor. For high-speed (or high-frequency) driving, a video may be more naturally expressed by raising the frequency of about 60 hertz (Hz) to about 120 Hz, but such a high-speed driving increases power consumption. A frequency when driving a still image may be reduced to compensate for the increased power consumption. In an embodiment, for example, when the still image is operated, it may be driven at about 1 Hz. When the frequency is reduced in this way, a leakage current may occur. In the display device according to an embodiment, the first transistor TR1, which is a switching transistor, may include an oxide semiconductor, thereby minimizing the leakage current. In such an embodiment, the second transistor TR2, which is a driving transistor, may include a polycrystalline semiconductor, thereby having a high degree of electron mobility. That is, the switching transistor and the driving transistor may include different semiconductor materials from each other, thereby driving more stably and having high reliability.

An encapsulation layer 600 is disposed on the common electrode 270. The encapsulation layer 600 may cover an upper surface as well as side surfaces of the display unit 100 to encapsulate the display unit 100. A new upper surface as well as side surfaces of the display unit 100 may be formed after the encapsulation layer 600 encapsulates the display unit 100.

The encapsulation layer 600 may include a plurality of layers, and may be formed as a composite layer including both an inorganic layer and an organic layer. In an embodiment, for example, the encapsulation layer 600 may include a triple layer in which a first encapsulation inorganic film, an encapsulation organic film, and a second encapsulation inorganic film are sequentially stacked one on another, the first encapsulation inorganic film and the second encapsulation inorganic film may include an inorganic material, and the encapsulation organic film may include an organic material.

The touch unit 200 is disposed on the encapsulation layer 600.

The touch unit 200 will be briefly described. A third insulating layer 710 is disposed on the encapsulation layer 600. The third insulating layer 710 may be formed as an inorganic layer or an organic layer such as a metal oxide, a metal oxynitride, a silicon oxide, a silicon nitride, and a silicon oxynitride. However, the embodiment is not limited thereto, and the third insulating layer 710 may include other materials.

The third insulating layer 710 may cover the encapsulation layer 600 to protect the encapsulation layer 600 and to prevent moisture permeation. In addition, the third insulating layer 710 may serve to reduce parasitic capacitance between the common electrode 270 and the touch electrode.

A first touch cell connector 452 is disposed on the third insulating layer 710, and the fourth insulating layer 720 is disposed on the first touch cell connector 452. The fourth insulating layer 720 may be formed as or defined by an inorganic layer or an organic layer such as a metal oxide, a metal oxynitride, a silicon oxide, a silicon nitride, and a silicon oxynitride. However, the embodiment is not limited thereto, and the fourth insulating layer 720 may include other materials.

A first touch cell TE is disposed on the fourth insulating layer 720. In addition, although not illustrated, a second touch cell and a second touch cell connector may also be disposed on the fourth insulating layer 720. In such an embodiment, one of the first touch cell TE and the second touch cell may serve as a sensing input electrode, and the other may serve as a sensing output electrode. The first touch cell TE and the second touch cell may be electrically separated from each other, and may be dispersed so as to not overlap each other to be disposed to have a mesh form. First touch cells TE may be connected to each other by the first touch cell connector 452, and second touch cells may be connected to each other by the second touch cell connector.

A touch cell protection layer 430 may be disposed on the first touch cells TE and the second touch cells (not illustrated). The touch cell protection layer 430 may protect the first touch cells TE and the second touch cells (not illustrated) by covering the first touch cells TE and the second touch cells (not illustrated) to prevent them from being exposed to the outside

The touch cell protection layer 430 may include an inorganic material such as a silicon nitride (SiNx) or a silicon oxide (SiO2), a polyacrylate resin, a polyimide resin, or an acrylic organic material. However, the embodiment is not limited thereto, and the touch cell protection layer 430 may include other materials.

The anti-reflection unit 300 is disposed on the touch unit 200.

The anti-reflection unit 300 includes a light blocking layer 520 and a color filter 530.

The light blocking layer 520 may overlap the pixel defining layer 350 of the display unit 100, and may be narrower than the pixel defining layer 350.

In an embodiment, a plurality of openings 521C may be defined through the light blocking layer 520 to overlap the pixel opening 365 of the pixel defining layer 350, and widths of the openings 521C of the light blocking layer 520 may be wider than the width of the overlapping pixel opening 365.

The color filter 530 is disposed on the light blocking layer 520. A part 530C of each color filter 530 is disposed in the openings 521C of the light blocking layer 520. A fifth insulating layer 540 may be disposed on the color filter 530.

The anti-reflection unit 300 prevents external light incident from the outside from being visually recognized by being reflected by a wire or the like. The light blocking layer 520 of the anti-reflection unit 300 is disposed to overlap an edge of an emission area, to absorbs incident external light to reduce the incident light to the emission area. Accordingly, a degree to which external light is reflected to be visually recognized may be effectively reduced.

The color filter 530 of the anti-reflection unit 3000 reduces reflection of external light incident from the outside to be visually recognized after being incident on the pixel defining layer 350. Since the color filter 530 does not completely block light, the reflected light of the external light may be effectively prevented from being visually recognized without reducing efficiency of the light emitted from the emission layer 370.

In general, a polarization layer may be used to prevent recognition of reflected light from external light, but this reduces efficiency of light emitted from the emission layer. However, according to an embodiment, the reflected light of the external light may be effectively prevented from being visually recognized through the anti-reflection unit 300 without reducing efficiency of the light emitted from the emission layer 370.

According to an embodiment illustrated in FIG. 4, for convenience of description, although the first transistor TR1, the second transistor TR2, and the light emitting diode LED connected to the second transistor TR2 are mainly illustrated, the embodiment is not limited thereto, and other transistors may be included in addition to the first transistor TR1 and the second transistor TR2. The first transistor TR1 may be a switching transistor, and the second transistor TR2 may be a driving transistor, but the embodiment is not limited thereto.

Referring to FIG. 5 together with FIG. 1, among edges of the display panel 10, a plurality of first pad portions PD1 for receiving signals from the outside of the display panel 10 may be disposed in the non-display area NDA disposed at a first edge E1 that is parallel to the first direction x. A plurality of second pad portions PD2 may be disposed at a first end portion E11 of the flexible printed circuit board 20. The second pad portion PD2 may be bonded to the first pad portion PD1, through which pads of the flexible printed circuit board 20 may be electrically connected to pads of the display panel 10.

An anisotropic conductive film may be disposed between the first pad portions PD1 and the second pad portions PD2 for mechanical and electrical bonding or connection between the first pad portions PD1 and the second pad portions PD2. The anisotropic conductive film may have a form in which conductive particles are dispersed in a thermosetting resin (e.g., a epoxy resin, an acrylic resin, a polyester resin, a bismaleimide resin, a cyanate resin, etc.) in the form of a film. However, the embodiment is not limited thereto, and the anisotropic conductive film may include other materials. The anisotropic conductive film may mechanically and electrically bond electronic components through a process that simultaneously applies heat and pressure.

The first pad portions PD1 of the display panel 10 may be spaced apart from each other along the first edge E1 of the display panel 10. The second pad portions PD2 of each of the flexible printed circuit boards 20 may be bonded to the corresponding first pad portions PD1.

A driving unit may be disposed in the non-display area NDA of the display panel 10 to generate and/or process various signals for driving the display panel 10. The driving unit may include: a data driver that applies a data signal to the data line 171, a gate driver that applies a gate signal to the first scan line 121 and the second scan line 122, and a signal controller that controls the data driver and the gate driver. The pixels PX may receive a data voltage or an initialization voltage at predetermined timing based on a scan signal generated by the gate driver. The gate driver may be integrated in the display panel 10, and may be disposed on at least one side of the display area DA.

The data driver may be provided as or defined by the integrated circuit chip 30. The integrated circuit chip 30 may be mounted in the flexible printed circuit board 20. Signals outputted from the integrated circuit chip 30 may be transferred to the display panel 10 through the second pad portions PD2 of the flexible printed circuit board 20 and the first pad portions PD1 of the display panel 10.

The display device 1000 may include a plurality of integrated circuit chips 30, and one integrated circuit chip 30 may be disposed on each flexible printed circuit board 20.

The signal controller may be provided as or defined by an integrated circuit chip, and may be mounted in the printed circuit board 40. The data driver and the signal controller may be provided as an integrated chip.

A pad portion disposed at a second end portion E22 opposite to the first end portion E11 of the flexible printed circuit board 20 may be bonded and electrically connected to the pad portion of the printed circuit board 40, thereby transferring signals between the display panel 10 and the printed circuit board 40. The printed circuit board 40 may include two or more pad portions, and the pad portions may be spaced apart from each other along one edge of the display panel 10. The printed circuit board 40 may include a plurality of pad portions, a number of which corresponds to a number of the flexible printed circuit boards 20.

The integrated circuit chip 30 may output signals supplied to the display area DA. In an embodiment, for example, the integrated circuit chip 30 may output a data voltage, a driving voltage, a common voltage, an initialization voltage, and the like. A data voltage transfer line, a driving voltage transfer line, a common voltage transfer line, and an initialization voltage transfer line for respectively transferring a data voltage, a driving voltage, a common voltage, and an initialization voltage outputted from the integrated circuit chip 30 to the data line 171, the driving voltage line 172, the common voltage line 173, and the initialization voltage line 174 of the display area DA may be disposed in the non-display area NDA. The integrated circuit chip 30 may also output signals for controlling the gate driver.

Signals outputted from the integrated circuit chip 30 may be inputted to the display panel 10 through the first pad portions PD1 connected to the second pad portions PD2 of the flexible printed circuit board 20. The integrated circuit chip 30 may receive signals, based on which the above signals (e.g., image data, related signals, power, etc.) are generated, through the pad portions of the flexible printed circuit board 20 connected to the pad portions of the printed circuit board 40. A processor, a memory, etc. may be disposed in the printed circuit board 40.

Referring to FIG. 6 and FIG. 7 together with FIG. 1 and FIG. 5, an embodiment of the display device 1000 may be curved along the first direction x around a direction parallel to the second direction y as a curvature axis. For example, the display device 1000 may be curved around a direction parallel to the second direction y so that the edge of the display device 1000 along the first direction x may be curved.

The flexible printed circuit board 20 may be bent around the first edge E1 of the display panel 10, and a portion of the flexible printed circuit board 20 and the printed circuit board 40 connected to the flexible printed circuit board 20 may be disposed on a rear surface 100a of the display panel 10.

In an embodiment, the flexible printed circuit board 20 of the display device 1000 includes a first flexible printed circuit board 21a adjacent to a center of the display panel 10 along the first direction x, and a second flexible printed circuit board 21b, a third flexible printed circuit board 21c, and a fourth flexible printed circuit board 21d sequentially disposed from the center of the display panel 10 toward a second edge Ea of the display panel 10 along the first direction x. In such an embodiment, the flexible printed circuit board 20 of the display device 1000 further includes a fifth flexible printed circuit board 22a adjacent to the center of the display panel 10 and adjacent to the first flexible printed circuit board 21a along the first direction x, and a sixth flexible printed circuit board 22b, a seventh flexible printed circuit board 22c, and an eighth flexible printed circuit board 22d sequentially disposed from the center of the display panel 10 in the first direction x toward a third edge Eb opposite to the second edge Ea of the display panel 10.

In such an embodiment, as shown in FIGS. 6 and 7, the display device 1000 may include four flexible printed circuit boards 21a, 21b, 21c, and 21d (i.e., first to fourth flexible printed circuit boards 21a, 21b, 21c, and 21d) sequentially disposed from the center of the display panel 10 toward the second edge Ea along the first direction x and four flexible printed circuit boards 22a, 22b, 22c, and 22d (i.e., fifth to eighth flexible printed circuit boards 22a, 22b, 22c, and 22d) sequentially disposed from the center of the display panel 10 toward the third edge Eb, but embodiments are not limited thereto, and the display device 1000 may include a plurality of flexible printed circuit boards (e.g., two, three, five or more flexible printed circuit boards) sequentially disposed from the center of the display panel 10 toward the second edge Ea along the first direction x and a plurality of flexible printed circuit boards (e.g., two, three, five or more flexible printed circuit boards) sequentially disposed from the center of the display panel 10 toward the third edge Eb.

The flexible printed circuit board 20 of the display device 1000 may be attached to the first edge E1 of the display panel 10. A first end portion E11 of each of the first flexible printed circuit boards 21a to the eighth flexible printed circuit board 22d of the flexible printed circuit board 20 may be attached to the first edge E1 of the display panel 10, and the second end portion E22 of each of the first flexible printed circuit board 21a to the eighth flexible printed circuit board 22d of the flexible printed circuit board 20 may be attached to the printed circuit board 40.

In such an embodiment, as described above, the display device 1000 may be curved along the first direction x to have a direction parallel to the second direction y as a curved axis (e.g., the display device 1000 may be curved around a direction parallel to the second direction y so that the edge of the display device 1000 along the first direction x may be curved), and the first edge E1 of the display panel 10 may be an edge parallel to the first direction x.

In such an embodiment, as shown in FIG. 1, the first end portion E11 of the first flexible printed circuit board 21a adjacent to the center of the display panel 10 and the first edge E1 of the display panel 10 along the first direction x of the flexible printed circuit board 20 of the display device 1000 are spaced apart to form a first distance D1a, the first end portion E11 of the second flexible printed circuit board 21b and the first edge E1 of the display panel 10 are spaced apart to form a second distance D1b, the first end portion E11 of the third flexible printed circuit board 21c and the first edge E1 of the display panel 10 are spaced apart to form a third distance D1c, and the first end portion E11 of the fourth flexible printed circuit board 21d and the first edge E1 of the display panel 10 are spaced apart to form a fourth distance D1d. In such an embodiment, the first distance D1a is the largest and the fourth distance D1d is the smallest, and the distance gradually decreases from the first distance D1a to the fourth distance D1d among the first distance D1a, the second distance D1b, the third distance D1c, and the fourth distance D1d. As such, the distance between the first end portion E11 of the flexible printed circuit board 20 and the first edge E1 of the display panel 10 is decreased as being away from the center of the display panel 10 toward the second edge Ea of the display panel 10 along the first direction x, which is the curved direction of the display device 1000 (e.g., the edge of the display device 1000 along the first direction x may be curved, similar to this hereinafter).

In such an embodiment, the first end portion E11 of the fifth flexible printed circuit board 22a adjacent to the center of the display panel 10 and the first edge E1 of the display panel 10 along the first direction x of the flexible printed circuit board 20 of the display device 1000 are spaced apart to form a fifth distance D2a, the first end portion E11 of the sixth flexible printed circuit board 22b and the first edge E1 of the display panel 10 are spaced apart to form a sixth distance D2b, the first end portion E11 of the seventh flexible printed circuit board 22c and the first edge E1 of the display panel 10 are spaced apart to form a seventh distance D2c, and the first end portion E11 of the eighth flexible printed circuit board 22d and the first edge E1 of the display panel 10 are spaced apart to form an eighth distance D2d. In such an embodiment, the fifth distance D2a is the largest and the eighth distance D2d is the smallest, and the distance gradually decreases from the fifth distance D2a to the eighth distance D2d among the fifth distance D2a, the sixth distance D2b, the seventh distance D2c, and the eighth distance D2d. As such, the distance between the first end portion E11 of the flexible printed circuit board 20 and the first edge E1 of the display panel 10 is decreased as being away from the center of the display panel 10 toward the third edge Eb of the display panel 10 along the first direction x, which is the curved direction of the display device 1000.

In an embodiment, as described above, the distance between the first end portion E11 of the flexible printed circuit board 20 and the first edge E1 of the display panel 10 is decreased as being away from the center of the display panel 10 toward the second and third edges Ea and Eb of the display panel 10 along the first direction x, which is the curved direction of the display device 1000. Accordingly, as illustrated in FIG. 6, from the center of the display panel 10 toward both edges Ea and Eb (i.e., the second and third edges Ea and Eb, similar to this hereinafter) of the display panel 10, along the second direction y, a length of a portion of each flexible printed circuit board 20 attached to the first edge E1 of the display panel 10 may become smaller, and a length of a portion that is bendable toward the rear surface 100a of the display panel 10 may be increased (e.g., a length along the second direction y of a portion of the flexible printed circuit boards 20 attached to the first edge E1 of the display panel 10 may become smaller, and a length along the second direction y of a portion that is bendable toward the rear surface 100a of the display panel 10 may be increased).

Referring to FIG. 8, in an embodiment, a plurality of second pad portions PD2 may be disposed at the first end portion E11 of the flexible printed circuit board 20, and each of the second pad portions PD2 of each flexible printed circuit board 20 may be disposed to form a predetermined distance from the first end portion E11 of the flexible printed circuit board 20.

In such an embodiment, as described above, since the portion of each flexible printed circuit board 20 attached to the first edge E1 of the display panel 10 decreases in length along the second direction y as being away from the center of the display panel 10 toward the second and third edges Ea and Eb of the display panel 10 (e.g., since the portion of the flexible printed circuit boards 20 attached to the first edge E1 of the display panel 10 decreases in length along the second direction y as being away from the center of the display panel 10 toward the second and third edges Ea and Eb of the display panel 10), a length along the second direction y of a portion overlapping the first edge E1 of the display panel 10 among the second pad portions PD2 may be shortened, and a length along the second direction y of the portion bent toward the rear surface 100a of the display panel 10 may be increased as being away from the center of the display panel 10 toward the second and third edges Ea and Eb of the display panel 10.

The display device 1000 may be curved along the first direction x to have a direction that is parallel to the second direction y as a curved axis (e.g., the display device 1000 may be curved around a direction parallel to the second direction y so that the edge of the display device 1000 along the first direction x may be curved), and a curved display device may be formed by applying a force to the second edge Ea and the third edge Eb of the display panel 10 facing each other along the first direction x during a manufacturing process to make the display device 1000 as a curved type.

Accordingly, a greatest stress may be applied to the fourth flexible printed circuit board 21d and the eighth flexible printed circuit board 22d disposed close to the second edge Ea and the third edge Eb of the display panel 10 among the flexible printed circuit board 20. A magnitude of the stress applied to each flexible printed circuit board 20 may increase as being away from the central portion (which may be referred to as center, similar to this hereinafter) of the display panel 10 toward the second edge Ea and the third edge Eb of the display panel 10 (e.g., a magnitude of the stress applied to the flexible printed circuit boards 20 may increase as being away from the central portion (which may be referred to as center, similar to this hereinafter) of the display panel 10 toward the second edge Ea and the third edge Eb of the display panel 10).

In accordance with an embodiment of the display device 1000, the distance between the first end portion E11 of the flexible printed circuit board 20 and the first edge E1 of the display panel 10 is decreased as being away from the center of the display panel 10 toward the second and third edges Ea and Eb of the display panel 10 along the first direction x, which is the curved direction of the display device 1000, and thus the length along the second direction y of a portion of each flexible printed circuit board 20 attached to the first edge E1 of the display panel 10 may become smaller, and the length along the second direction y of a portion that is bendable toward the rear surface 100a of the display panel 10 may be increased (e.g., the length along the second direction y of a portion of the flexible printed circuit boards 20 attached to the first edge E1 of the display panel 10 may become smaller, and the length along the second direction y of a portion that is bendable toward the rear surface 100a of the display panel 10 may be increased,), from the center of the display panel 10 toward both edges Ea and Eb of the display panel 10.

Accordingly, even when a stress of a magnitude that increases as being away from the central portion of the display panel 10 to the second edge Ea and the third edge Eb of the display panel 10 is applied to each flexible printed circuit board 20, the portion of each flexible printed circuit board 20 that is bendable toward the rear surface 100a of the display panel 10 becomes longer (e.g., even when a stress of a magnitude that increases as being away from the central portion of the display panel 10 to the second edge Ea and the third edge Eb of the display panel 10 is applied to the flexible printed circuit boards 20, the portion of the flexible printed circuit boards 20 that is bendable toward the rear surface 100a of the display panel 10 becomes longer), and thus each flexible printed circuit board 20 may be effectively prevented from being separated from the display panel 10, that is, separation between the flexible printed circuit board 20 and the display panel 10 by a stress may be effectively prevented.

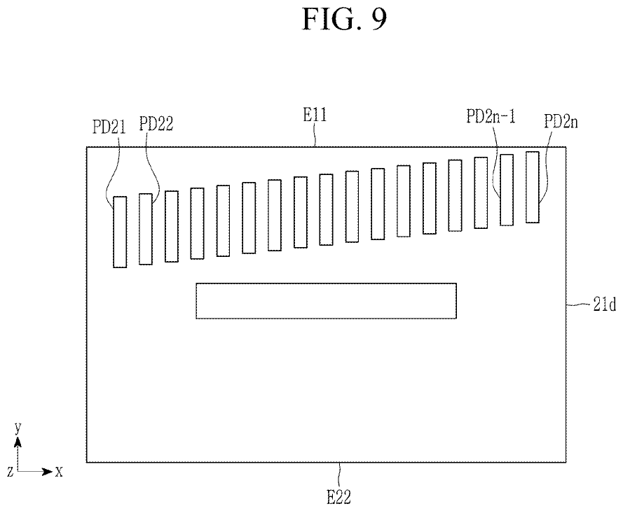

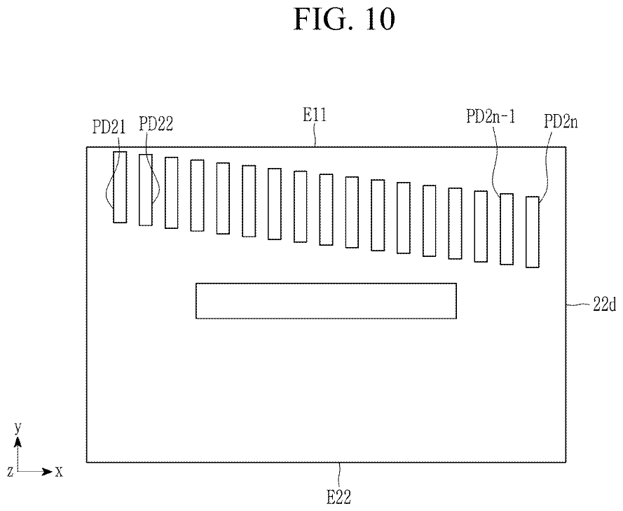

Next, an alternative embodiment of a display device will be described with reference to FIG. 9 and FIG. 10 together with FIG. 1 to FIG. 7. FIG. 9 and FIG. 10 each illustrate a top plan view showing a portion of a display device according to an alternative embodiment.

An embodiment of the display device shown in FIG. 9 and FIG. 10 is substantially the same as embodiments of the display device described above with reference to FIG. 1 to FIG. 8. Accordingly, any repetitive detailed description of the same or like constituent elements will be omitted.

In an embodiment, referring to FIG. 9 and FIG. 10, the second pad portions PD2 disposed in the flexible printed circuit board 20 of the display device 1000 according to the present embodiment may include a first pad PD21, a second pad PD22, . . . , an (n−1)^{th} pad PD2n−1, and an n^{th} pad PD2n sequentially disposed along the first direction x.

The flexible printed circuit board 20 may be disposed to be gradually closer to the first end portion E11 and gradually farther away from the second end portion E22 of the flexible printed circuit board 20 from the first pad PD21 to the n^{th} pad PD2n of the second pad portions PD2 of the flexible printed circuit board 20 disposed at the second edge Ea of the display panel 10 based on the center of the display panel 10 along the first direction x.

In such an embodiment, the flexible printed circuit board 20 may be disposed to be gradually farther away from the first end portion E11 and gradually closer to the second end portion E22 of the flexible printed circuit board 20 from the first pad PD21 to the n^{th} pad PD2n of the plurality of second pad portions PD2 of the flexible printed circuit boards 20 disposed at the third edge Eb of the display panel 10 based on the center of the display panel 10 along the first direction x.

FIG. 9 illustrates an embodiment of the fourth flexible printed circuit board 21d adjacent to the second edge Ea of the display panel 10 of the display device 1000. In an embodiment, as described above with reference to FIG. 1, FIG. 6, and FIG. 7, the fourth flexible printed circuit board 21d is disposed at the second edge Ea of the display panel with respect to the center of the display panel 10 along the first direction x, and as illustrated in FIG. 9, the plurality of second pad portions PD2 is disposed gradually closer to the first end portion E11 of the flexible printed circuit board 20 (e.g., the fourth flexible printed circuit board 21d) and gradually farther away from the second end portion E22 of the flexible printed circuit board 20 (e.g., the fourth flexible printed circuit board 21d) from the first pad PD21 of the second pad portions PD2 of the fourth flexible printed circuit board 21d to the n^{th} pad PD2n.

FIG. 10 illustrates an embodiment of an eighth flexible printed circuit board 22d adjacent to the third edge Eb of the display panel 10 of the display device 1000. In an embodiment, as described above with reference to FIG. 1, FIG. 6, and FIG. 7, the eighth flexible printed circuit board 22d is disposed at the third edge Eb of the display panel with respect to the center of the display panel 10 along the first direction x, and as illustrated in FIG. 10, the plurality of second pad portions PD2 is disposed gradually farther away from the first end portion E11 of the flexible printed circuit board 20 (e.g., the eighth flexible printed circuit board 22d) and gradually closer to the second end portion E22 of the flexible printed circuit board 20 (e.g., the eighth flexible printed circuit board 22d) from the first pad PD21 of the second pad portions PD2 of the eighth flexible printed circuit board 22d to the n^{th} pad PD2n.

In such an embodiment, the second pad portions PD2 disposed on each flexible printed circuit board 20 are disposed to be gradually farther away from the first end portion E11 and to be gradually closer to the second end portion E22 as the flexible printed circuit board 20 is disposed closer to opposite edges of the display panel 10 facing each other along the first direction x, and thus the length along the second direction y of the portion of each flexible printed circuit board 20 attached to the first edge E1 of the display panel 10 may become smaller, and the length along the second direction y of the portion that is bendable toward the rear surface 100a of the display panel 10 may be increased among the second pad portions PD2, from the center of the display panel 10 toward the second and third edges Ea and Eb of the display panel 10.

In such an embodiment, even when a stress of a magnitude that increases from the central portion of the display panel 10 to the second edge Ea and the third edge Eb of the display panel 10 is applied to each flexible printed circuit board 20, the length of the portion bendable toward the rear surface 100a of the display panel 10 among the second pad portions PD2 of each flexible printed circuit board 20 is increased, and thus each flexible printed circuit board 20 may prevent the second pad portions PD2 from being separated from the display panel 10 due to the stress.

In embodiments, as described above with reference to FIG. 1 to FIG. 7, the distance between the first end portion E11 of the flexible printed circuit board 20 and the first edge E1 of the display panel 10 is decreased as being away from the center of the display panel 10 toward the edges Ea and Eb of the display panel 10 along the first direction x, which is the curved direction of the display device 1000, and thus the length along the second direction y of a portion of each flexible printed circuit board 20 attached to the first edge E1 of the display panel 10 may become smaller, and the length along the second direction y of a portion that is bendable toward the rear surface 100a of the display panel 10 may be increased (e.g., the length along the second direction y of a portion of the flexible printed circuit boards 20 attached to the first edge E1 of the display panel 10 may become smaller, and the length along the second direction y of a portion that is bendable toward the rear surface 100a of the display panel 10 may be increased) from the center of the display panel 10 toward both edges Ea and Eb of the display panel 10.

Accordingly, even when a stress of a magnitude that increases from the central portion of the display panel 10 to the second edge Ea and the third edge Eb of the display panel 10 is applied to each flexible printed circuit board 20, the portion of each flexible printed circuit board 20 that is bendable toward the rear surface 100a of the display panel 10 becomes longer (e.g., even when a stress of a magnitude that increases from the central portion of the display panel 10 to the second edge Ea and the third edge Eb of the display panel 10 is applied to the flexible printed circuit boards 20, the portion of the flexible printed circuit boards 20 that is bendable toward the rear surface 100a of the display panel 10 becomes longer), and thus each flexible printed circuit board 20 may be effectively prevented from being separated from the display panel 10 by a stress, that is, separation between the flexible printed circuit board 20 and display panel 10 may be effectively prevented.

Other features of the embodiment of the display device shown in FIG.9 and FIG. 10 are substantially the same as those of the embodiment described above with reference to FIG. 1 to FIG. 8.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel comprising a display area including a plurality of pixels and a non-display area disposed around the display area; and
a plurality of flexible printed circuit boards disposed in the non-display area along a first edge of the display panel,
wherein distances of a first end portion of each of the flexible printed circuit boards from the first edge are different from each other.

2. The display device of claim 1, wherein
the first edge is parallel to a first direction, and
the display panel is curved around an axis in a second direction which is perpendicular to the first direction.

3. The display device of claim 2, wherein
the display panel includes a second edge and a third edge, which are connected to the first edge and opposite to each other in the first direction,
the flexible printed circuit boards include a first flexible printed circuit board disposed at a center of the display panel and a second flexible printed circuit board disposed adjacent to the second edge of the display panel, and
a first distance between the first end portion of the first flexible printed circuit board and the first edge is greater than a second distance between the first end portion of the second flexible printed circuit board and the first edge.

4. The display device of claim 3, wherein
the flexible printed circuit boards further include a third flexible printed circuit board and a fourth flexible printed circuit board, which are disposed between the first flexible printed circuit board and the second flexible printed circuit board,
the third flexible printed circuit board is disposed closer to the first flexible printed circuit board than to the second flexible printed circuit board,
the fourth flexible printed circuit board is disposed closer to the second flexible printed circuit board than to the first flexible printed circuit board, and
a third distance between the first end portion of the third flexible printed circuit board and the first edge is smaller than a fourth distance between the first end portion of the fourth flexible printed circuit board and the first edge.

5. The display device of claim 4, wherein
the first distance is greater than the third distance, and
the second distance is smaller than the fourth distance.

6. The display device of claim 2, further comprising:
a plurality of first pad portions disposed in the display panel; and
a plurality of second pad portions disposed in each of the flexible printed circuit boards,
wherein the first pad portions are in contact with the second pad portions.

7. The display device of claim 6, wherein
the display panel includes a second edge and a third edge, which are connected to the first edge and opposite to each other in the first direction, and
distances of each of the second pad portions from the first end portion are different from each other.

8. The display device of claim 7, wherein
the second pad portions are disposed to be farther away from the first end portions as being closer to the second edge or the third edge from a center of the display panel in the first direction.

9. A display device comprising:
a display panel comprising a display area including a plurality of pixels and a non-display area disposed around the display area;
a plurality of flexible printed circuit boards disposed in the non-display area along a first edge of the display panel;
a plurality of first pad portions disposed in the display panel; and
a plurality of second pad portions disposed in each of the flexible printed circuit boards,
wherein distances of a first end portions of each of the flexible printed circuit boards from the first edge are different from each other, and
distances of each of the second pad portions from the first end portion are different from each other.

10. The display device of claim 9, wherein
the first edge is parallel to a first direction, and
the display panel is curved around an axis in a second direction which is perpendicular to the first direction.

11. The display device of claim 10, wherein
the first pad portions are in contact with the second pad portions.

12. The display device of claim 11, wherein
the display panel includes a second edge and a third edge, which are connected to the first edge and opposite to each other in the first direction, and
the second pad portions are disposed to be farther away from the first end portions as being closer to the second edge or the third edge from a center of the display panel in the first direction.

13. The display device of claim 10, wherein
the flexible printed circuit boards include a first flexible printed circuit board disposed at a center of the display panel and a second flexible printed circuit board disposed adjacent to a second edge of the display panel, and
a first distance between the first end portion of the first flexible printed circuit board and the first edge is greater than a second distance between the first end portion of the second flexible printed circuit board and the first edge.

14. The display device of claim 13, wherein
the flexible printed circuit boards further include a third flexible printed circuit board and a fourth flexible printed circuit board, which are disposed between the first flexible printed circuit board and the second flexible printed circuit board,
the third flexible printed circuit board is disposed closer to the first flexible printed circuit board than the second flexible printed circuit board is,
the fourth flexible printed circuit board is disposed closer to the second flexible printed circuit board than the first flexible printed circuit board is, and
a third distance between the first end portion of the third flexible printed circuit board and the first edge is greater than a fourth distance between the first end portion of the fourth flexible printed circuit board and the first edge.

15. The display device of claim 14, wherein
the first distance is greater than the third distance, and
the second distance is smaller than the fourth distance.

16. A display device comprising:
a display panel comprising a display area including a plurality of pixels and a non-display area disposed around the display area, wherein the display panel includes a first edge which is parallel to a first direction, and a second edge and a third edge which are connected to the first edge and opposite to each other in the first direction;
a plurality of flexible printed circuit boards disposed in the non-display area along the first edge of the display panel;
a plurality of first pad portions disposed in the display panel; and
a plurality of second pad portions disposed in each of the flexible printed circuit boards and connected to the first pad portions,
wherein
the second pad portions are disposed to be farther away from a first end portion of each of the flexible printed circuit boards as being closer to the second edge or the third edge from a center of the display panel in the first direction.

17. The display device of claim 16, wherein
the first edge is parallel to a first direction, and
the display panel is curved around an axis in a second direction which is perpendicular to the first direction.

18. The display device of claim 17, wherein
the first pad portions are in contact with the second pad portions.

19. The display device of claim 18, wherein
the flexible printed circuit boards include a first flexible printed circuit board disposed at the center of the display panel and a second flexible printed circuit board disposed adjacent to a second edge of the display panel, and
a first distance between the first end portion of the first flexible printed circuit board and the first edge is greater than a second distance between the first end portion of the second flexible printed circuit board and the first edge.

20. The display device of claim 19, wherein
The flexible printed circuit boards further include a third flexible printed circuit board and a fourth flexible printed circuit board, which are disposed between the first flexible printed circuit board and the second flexible printed circuit board,
the third flexible printed circuit board is disposed closer to the first flexible printed circuit board than the second flexible printed circuit board is,
the fourth flexible printed circuit board is disposed closer to the second flexible printed circuit board than the first flexible printed circuit board is, and
a third distance between the first end portion of the third flexible printed circuit board and the first edge is greater than a fourth distance between the first end portion of the fourth flexible printed circuit board and the first edge.
